(19) United States
(12) Patent Application Publication
(10) Pub. No.: US 2018/0324978 A1
(43) Pub. Date: Nov. 8, 2018

(54) HEAT DISSIPATION DEVICE

(71) Applicant: KAI HUI LIN, Taipei City (TW)

(72) Inventor: KAI HUI LIN, Taipei City (TW)

(21) Appl. No.: 15/584,038

(22) Filed: May 2, 2017

(51) Int. Cl. H05K 7/20; F28D 15/02; F28F 1/02; F28F 1/12

(52) U.S. Cl. CPC H05K 7/20336; F28D 15/0233; F28F 1/02; F28F 2275/025; H05K 7/20409; H05K 7/20172; F28F 1/12

(57) ABSTRACT

A heat dissipation device includes a flat heat conductive unit having a flat sealed chamber and a fluid flowing within the flat sealed chamber; the flat sealed chamber including a heat dissipation surface, a heat absorption surface and a peripheral surface; the heat dissipation surface being arranged opposite to the heat absorption surface and the peripheral surface being arranged between the heat dissipation surface and the heat absorption surface; a heat dissipating wall installed and standing on the heat dissipation surface and being enclosed as a receiving space; and a fan received within the receiving space. The heat dissipation device comprises a cover covering on the heat dissipating wall. The cover is a heat dissipation cover and is formed with at least one heat dissipation hole. The cover is adhered to the heat dissipating wall by using heat conducive glue. The cover further includes a fin set.

### FIELD OF THE INVENTION

The present invention is related to heat dissipation, and in particular to a heat dissipation device.

### BACKGROUND OF THE INVENTION

Electronic elements in electronic devices may generate heat, especially, processing units, such as central proceeding units or graphic processing units which operate with very high speeds. These processing units are main heat sources of electronic devices. When the operation speeds or amounts of operations become larger and larger, the heat generates become greater and greater. This will induce that the temperatures of the electronic devices increase and thus affect operations of the devices. Thereby, lifetimes of the electronic devices are shortened. As a result, the steadiness of the electronic devices becomes worse. Therefore heat dissipation devices are needed to resolve such problem.

Currently, a kind of heat dissipation device which combines heat dissipative tubes and fans is developed. The heat conductive tube is a long tube and one end of the heat conductive tube is connected to a heat source and another end thereof is connected to the fan. Heat from the heat source is transferred to the fan through the heat conductive tube and then heat is fanned out by the convention of the air. Thereby, heat from the heat dissipation device is dispersed by the heat dissipation device so as to limit temperatures within the electronic device is well controlled. In this heat dissipation way, heat conduction is achieved by a one dimensional heat dissipation mode.

### SUMMARY OF THE INVENTION

Accordingly, the object of the present invention is to provide a heat dissipation device comprising: a flat heat conductive unit having a flat sealed chamber and a fluid flowing within the flat sealed chamber; the flat sealed chamber including a heat dissipation surface, a heat absorption surface and a peripheral surface; the heat dissipation surface being arranged opposite to the heat absorption surface and the peripheral surface being arranged between the heat dissipation surface and the heat absorption surface; a heat dissipating wall installed and standing on the heat dissipation surface and being enclosed as a receiving space; and a fan received within the receiving space.

The heat dissipation device comprises a cover covering on the heat dissipating wall. The cover is a heat dissipation cover and is formed with at least one heat dissipation hole which is communicated with the receiving space. The cover is adhered to the heat dissipating wall by using heat conducive glue. The cover further includes a fin set.

The fan is pivotally installed on the cover. The heat dissipating wall includes at least one heat dissipating opening which is communicated to the receiving space. The heat dissipation device 10 further comprises a fin set installed on the heat dissipation surface. The heat dissipating wall and the heat dissipation surface are adhered by heat conductive glue. The flat heat conductive unit is a flat heat conductive tube or a heat conductive plate.

### BRIEF DESCRIPTION OF THE DRAWINGS

FIG. 1 is a schematic view showing the heat dissipation device according to the first embodiment.

FIG. 2 is a cross sectional view viewed along line 2-2 of FIG. 1.

FIG. 3 is a schematic view showing the heat dissipation device in the second embodiment of the present invention.

FIG. 4 is a schematic view viewed along line 4-4 of FIG. 3.

FIG. 5 is a schematic view about the heat dissipation device of the third embodiment of the present invention.

FIG. 6 is a schematic view showing the heat dissipation device in the fourth embodiment of the present invention.

FIG. 7 is an exploded view about the heat dissipation device in the fifth embodiment of the present invention.

FIG. 8 is a schematic view showing the heat dissipation device of fifth embodiment of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

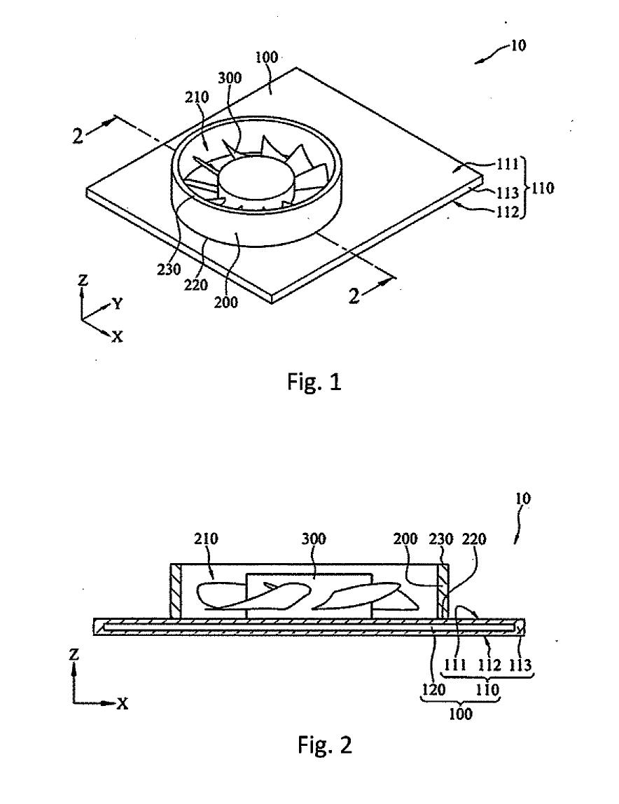

With reference to FIGS. 1 and 2, in this embodiment, the heat dissipation device 10 is installed within an electronic device (such as a notebook) and is connected to a heat source (for example, a chip). The heat dissipation device 10 comprises a flat heat conductive unit 100, a heat dissipating wall 200, and a fan 300. The flat heat conductive unit 100 comprises a flat sealed chamber 110 and a fluid 120. The flat sealed chamber 110 has a sealed inner space and fluid 120 is filled within the sealed inner space of the flat sealed chamber 110. Material of the wall of the flat sealed chamber 110 is high conductive, such as aluminum or copper, or complex material. The fluid 120 may be liquid or air which flows within the flat sealed chamber 110 and has the function of heat conduction. The flat heat conductive unit 100 is a flat heat conductive tube or a heat conductive plate.

With reference to FIGS. 1 and 2, the flat sealed chamber 110 includes a heat dissipation surface 11, a heat absorption surface 112 and a peripheral surface 113. The heat dissipation surface 111 is opposite to the heat absorption surface 112 and the peripheral surface 113 is arranged between the heat dissipation surface 111 and the heat absorption surface 112. In this embodiment, the heat dissipation surface 111 is parallel to and has an equal area to that of the heat absorption surface 112. However, this is not used to confine the scope of the present invention.

For example, in the coordinate system illustrated in FIGS. 1 and 2, the heat dissipation surface 111 and the heat absorption surface 112 are parallel to the XY planes and the peripheral surface 113 is on the Z surface and is connected to the heat dissipation surface 111 and the heat absorption surface 112. The areas of the heat dissipation surface 111 and the heat absorption surface 112 are greater than that of the peripheral surface 113. Therefore the flat heat conductive unit 100 has a flat structure. The surfaces on the X and Y planes are greater and the surface of the Z plane is smaller. For example, lengths and widths of the heat dissipating wall 200 and the heat absorption surface 112 are between 50 mm to 100 mm. The thickness in Z direction of the flat heat conductive unit 100 is about 5 mm. Above example is only used to a flat structure, but it is not used to confine the scope of the present invention.

Referring to FIGS. 1 and 2, the heat dissipating wall 200 is stand and installed on the heat dissipation surface 111 along the Z direction.

The heat dissipating wall 200 enclose as a circle so as to form as a receiving space 210. In this embodiment, the heat dissipating wall 200 is vertical to the heat dissipation surface 111 and the heat dissipating wall 200 encloses as a round receiving space 210. The heat dissipating wall 200 includes an annular bottom side 22—and an annular top side 230. The annular bottom side 220 is connected to the heat dissipation surface 111 and the annular top side 220 is far away from the heat dissipation surface 111. The material of the heat dissipating wall 200 is highly heat conductive, such as aluminum or copper, or other complex material. The fan 300 is received in the receiving space 210. The heat absorption surface 112 of the flat heat conductive unit 100 is used to connect to a heat source (not shown). The heat source may be a chip or a processor.

With reference to FIGS. 1 and 2, the heat absorption surface 112 absorbs heat from the heat source and is dispersed three dimensionally (X, Y and Z directions). That is to say, the flat sealed chamber 110 cause absorbed heat to be dispersed on the heat dissipation surface 111 and the peripheral surface 113. The fluid 120 has the effect of enhancing heat conduction. Therefore heat absorbed from the flat heat conductive unit 100 will disperse to the heat dissipation surface 111, heat absorption surface 112 and the peripheral surface 113 quickly and effectively. Furthermore, heat can be transferred to the heat dissipating wall 200 from the heat dissipation surface 111 so as to dissipate heat effectively.

The rotation of fan 300 will cause heat from the flat heat conductive unit 100 and the heat dissipating wall 200 to be dispersed effectively. In the present invention, the flat heat conductive unit 100 and the heat dissipating wall 200 has high heat dispersion effect and thus the rotation speed of the fan 300 can be reduced to reduce the noise generated.

In this embodiment, both of the heat dissipation surface 111 and the heat absorption surface 112 have the functions of heat dissipation and the heat absorption. That is to say, a heat source (not shown) can be connected to the heat dissipation surface 111. At this situation, the heat from the heat source is dissipated through the heat dissipation surface 111 to the flat heat conductive unit 100 and is dissipated through the heat dissipation surface 111 and the heat absorption surface 112.

In one embodiment, head conductive glue (not shown) is filled between the heat dissipating wall 200 and the heat dissipation surface 111. The annular bottom surface 220 of the heat dissipating wall 200 is connected to the heat dissipation surface 111 through the heat conductive glue. Thereby, the heat from the heat dissipation surface 111 can be effectively transferred to the heat dissipating wall 200. In another embodiment, the heat dissipating wall 200 and the flat heat conductive unit 100 are integrally formed. Or the heat dissipating wall 200 is connected to the flat heat conductive unit 100 through screws, buckles, tightly connection, heat connection, tin welding, aluminum tightening connection, and other ways.

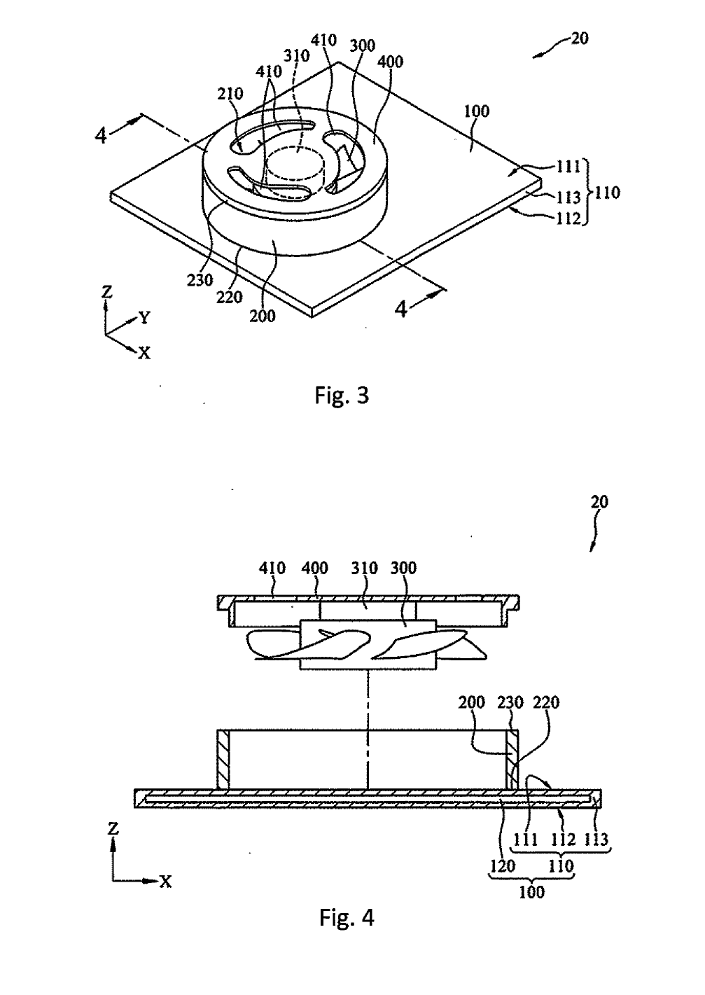

With reference to FIGS. 3 and 4, the second embodiment of the present invention is illustrated.

The difference between the first and second embodiment is that: the heat dissipation device 20 in the second embodiment further comprises a cover 400. Furthermore, the fan 300 in the second embodiment is installed on the cover 400. All other components in the first and second embodiments are identical and thus the details thereof will not be further described herein. In this embodiment, the cover 400 covers on the heat dissipating wall 200. The edge of the cover 400 is connected to the annular top end of the heat dissipating wall 200. The fan 300 is installed on the cover 400 through a pivotal shaft 310. Furthermore, the cover 400 is formed with a plurality of heat dissipation holes 410 which is communicated with the receiving space 210. When the fan 300 operates, the heat dissipation hole 410 serves to enhance airflow.

In this embodiment, the cover 400 is a heat dissipation cover of high heat conductivity, and is made of material such as aluminum or copper, or other complex material. This is to say, when the heat dissipation device 20 dissipates heat, the flat heat conductive unit 100 will absorb heat. Other than dissipating heat from the heat dissipation surface 111 to the heat dissipating wall 200, the heat dissipating wall 200 can further dissipate heat to the cover to increase the heat dissipation efficiency.

In one embodiment, a heat conductive glue is applied to be between the heat dissipating wall 200 and the cover 400. The annular top end of the heat dissipating wall 200 is connected to the cover 400 through the heat conductive glue. In another embodiment, the heat dissipating wall 200 is integrally formed with the cover 400. Or the heat dissipating wall 200 is combined with the cover 400 by screwing, buckling, tightening connection , heat melting connection, tin welding, aluminum extrusion, etc.

In another embodiment, the cover has fins (not shown) which is far away from the heat dissipation surface 111. Thereby, heat can be further dissipated to the fins to increase heat dissipation effect.

In one embodiment, the cover 400 is formed with a plurality of arms (not shown). A plurality of heat dissipation holes are formed between the arms. For example, the arms are formed as the bones of an umbrella, the gaps between two arms are used as heat dissipation holes.

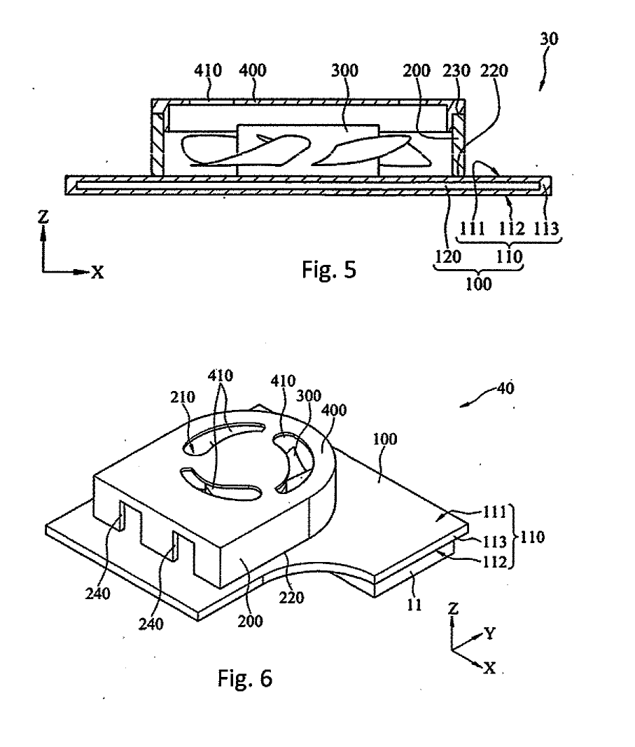

With reference to FIGS. 5, FIG. 5 shows the third embodiment of the present invention, in that the difference between the third and second embodiment is that: the fan 300 of the heat dissipation device 30 in the third embodiment is pivotally installed on the flat heat conductive unit 100. Other elements of the second and third embodiments are identical and thus the details thereof will not be further described herein. In this embodiment, the fan 300 is connected to the flat heat conductive unit 100 by using pivotal shafts (not shown). One end of the pivotal shaft is installed on the heat dissipation surface 111 and the fan 300 is pivotally installed on the pivotal shafts.

In one embodiment, the fan 300 is pivotally secured to a supporting frame (not shown). The supporting frame is firmly secured to the cover 400, or the supporting frame is secured to the heat dissipating wall 200 or the heat dissipation surface 111.

With reference to FIG. 6, the fourth embodiment of the present invention is illustrated. In the fourth embodiment, the heat dissipating wall 200 has a U shape structure with at least one heat dissipating opening 240. The heat dissipation surface 111 has an L shape structure. Other elements are identical in second and fourth embodiments and thus are not described herein. The structure in the fourth embodiment serves to fit different structure of electronic devices for enhancing heat dissipation effect.

With reference to FIGS. 6, the heat absorption surface 112 of the flat sealed chamber 110 is connected to a chip 11. Heat from the chip 11 can be dispersed to the heat dissipation surface 111 and the heat dissipating wall 200 through the heat absorption surface 112 and the fluid 120. One side of the heat dissipating wall 200 is formed with two heat dissipation openings 240 which are communicated to the receiving space 210. When the fan 300 operates, the heat dissipation openings 240 of the heat dissipating wall 200 and the heat dissipation hole 410 of the cover 400 can be as wind inlet and outlet for enhancing heat dissipation effect.

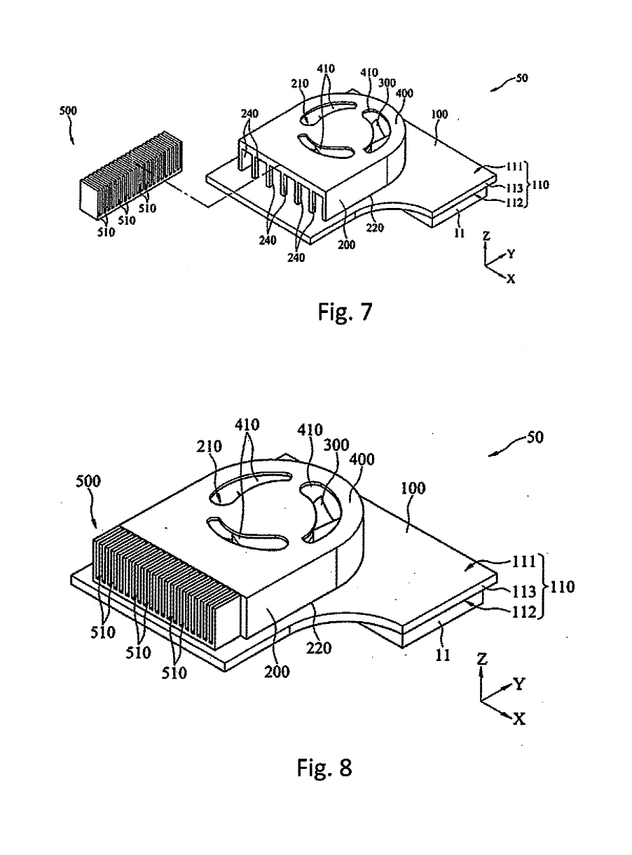

With reference to FIGS. 7 and 8, in this embodiment, the heat dissipation device 50 further has a fin set 500. The heat dissipating wall 200 has at least two heat dissipation openings 240. The fin set 500 is installed on the heat dissipation surface 111 and has a plurality of fins 510 which are arranged with a space one by one. Furthermore, heat absorbed by the flat heat conductive unit 100 may be further dissipated from the fin 510. In this embodiment, one side of the fin set 500 is adjacent to the heat dissipating wall 200. Therefore, the heat absorbed by the flat heat conductive unit 100 can be diffused to the fin set 500 through the heat dissipation surface 111 and the heat dissipating wall 200.

Installation of the fins 510 is corresponding to the heat dissipation openings 240 of the heat dissipating wall 200. Therefore when fan 300 operates, air flowing through the heat dissipation openings 240 can further pass through the gaps between the fins 510 so as to dissipating heat on the fins 510. Therefore the heat dissipation efficiency is enhanced.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A heat dissipation device comprising:
a flat heat conductive unit having a flat sealed chamber and a fluid flowing within the flat sealed chamber; the flat sealed chamber including a heat dissipation surface, a heat absorption surface and a peripheral surface; the heat dissipation surface being arranged opposite to the heat absorption surface and the peripheral surface being arranged between the heat dissipation surface and the heat absorption surface;
a heat dissipating wall installed and standing on the heat dissipation surface and being enclosed as a receiving space; and
a fan received within the receiving space.

2. The heat dissipation device as claimed in claim 1, further comprising a cover covering on the heat dissipating wall.

3. The heat dissipation device as claimed in claim 1, wherein the cover is a heat dissipation cover.

4. The heat dissipation device as claimed in claim 2, wherein the cover is formed with at least one heat dissipation hole which is communicated with the receiving space.

5. The heat dissipation device as claimed in claim 3, wherein the cover is adhered to the heat dissipating wall by using heat conducive glue.

6. The heat dissipation device as claimed in claim 3, wherein the cover further includes a fin set.

7. The heat dissipation device as claimed in claim 2, wherein the fan is pivotally installed on the cover.

8. The heat dissipation device as claimed in claim 1, wherein the heat dissipating wall includes at least one heat dissipating opening which is communicated to the receiving space.

9. The heat dissipation device as claimed in claim 1, further comprising a fin set installed on the heat dissipation surface.

10. The heat dissipation device as claimed in claim 1, wherein the heat dissipating wall and the heat dissipation surface are adhered by heat conductive glue.

11. The heat dissipation device as claimed in claim 1, wherein the flat heat conductive unit is a flat heat conductive tube or a heat conductive plate.
